(19) United States
(12) Patent Application Publication
(10) Pub. No.: US 2025/0324617 A1
(43) Pub. Date: Oct. 16, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 18/789,692

(22) Filed: Jul. 31, 2024

(30) Foreign Application Priority Data
Apr. 16, 2024 (KR) 10-2024-0050446

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511; H01L 2924/351

(57) ABSTRACT

A semiconductor device may include a first interlayer insulating layer; a second interlayer insulating layer disposed on the first interlayer insulating layer; a first bonding pad disposed in the first interlayer insulating layer; a second bonding pad disposed in the second interlayer insulating layer and connected to the first bonding pad; a first bonding via penetrating through the first bonding pad; a second bonding via penetrating through the second bonding pad and connected to the first bonding via; a first dummy insulating pillar extending through the first interlayer insulating layer; and a second dummy insulating pillar extending through the second interlayer insulating layer and connected to the first dummy insulating pillar.

### CROSS-REFERENCE TO RELATED APPLICATION

This patent application claims priority under 35 U.S.C. § 119 to Korean Patent Application No. 10-2024-0050446 filed on Apr. 16, 2024, which is incorporated herein by reference in its entirety.

### BACKGROUND

### 1. Technical Field

Embodiments of the present disclosure relate generally to semiconductor technology, and more particularly, to a semiconductor device and a manufacturing method of the semiconductor device.

### 2. Related ART

The integration degree of a semiconductor device (also known as integration density) is mainly determined by the footprint of each unit memory cell. Recently, as improvements in the integration density of a two-dimensional semiconductor device (forming memory cells in a single layer over a substrate) have reached an insurmountable limit, a three-dimensional semiconductor device has been proposed.

A three-dimensional (3D) semiconductor device is a type of integrated circuit (IC) that incorporates multiple layers of semiconductor materials or components stacked vertically to enhance performance and reduce space compared to traditional two-dimensional (2D) planar designs. This vertical stacking allows for shorter interconnects, improved electrical characteristics, and better use of silicon real estate.

Examples of 3D semiconductor devices include 3D NAND flash memory, i.e., a non-volatile memory where memory cells are stacked vertically in multiple layers over a substrate to increase storage density and improve performance. Another example is 3D integrated Circuits (3D ICs) where multiple silicon wafers or dies are stacked and interconnected with through-silicon vias (TSVs). This technology enhances performance, reduces power consumption, and decreases the overall footprint of the device. These 3D semiconductor structures are increasingly used in advanced semiconductor technologies for higher performance and efficiency in a smaller footprint.

However, 3D semiconductor devices are relatively new and further improvements in performance and operational reliability are being explored by employing different novel el structures and manufacturing methods.

### SUMMARY

According to an embodiment of the present disclosure there is provided a semiconductor device including a first interlayer insulating layer, a second interlayer insulating layer disposed on the first interlayer insulating layer, a first bonding pad disposed in the first interlayer insulating layer, and a second bonding pad disposed in the second interlayer insulating layer and connected to the first bonding pad. the semiconductor device may further include a first bonding via penetrating through the first bonding pad, a second bonding via penetrating through the second bonding pad and connected to the first bonding via and first and second dummy insulating pillars extending through the first and second interlayer insulating layers, respectively. The second dummy insulating pillar may be connected to the first dummy insulating pillar.

According to another embodiment of the present disclosure, there is provided a semiconductor device including a substrate including chip regions and a scribe lane region disposed between the chip regions, a first interlayer insulating layer disposed in the chip regions and the scribe lane region, a second interlayer insulating layer disposed on the first interlayer insulating layer, a first bonding pad disposed in the first interlayer insulating layer, in the chip regions, and a second bonding pad disposed in the second interlayer insulating layer and connected to the first bonding pad. The semiconductor device may further include a first bonding via penetrating through the first bonding pad and a second bonding via penetrating through the second bonding pad and connected to the first bonding via, and first and second dummy insulating pillars extending through the first and second interlayer insulating layers, respectively. The second dummy insulating pillar may be connected to the first dummy insulating pillar.

According to yet another embodiment of the present disclosure, a manufacturing method of a semiconductor device is provided. The manufacturing method may include: forming an interlayer insulating layer on a substrate; forming a bonding via and a first dummy bonding via extending through the interlayer insulating layer; forming a trench exposing a portion of a sidewall of the bonding via; forming a bonding pad in the trench using the bonding via and the first dummy bonding via as a planarization barrier; forming a first dummy hole by removing the first dummy bonding via; and forming a first dummy insulating pillar in the first dummy hole.

According to yet another embodiment of the present disclosure, a manufacturing method of a semiconductor device may include forming a first interlayer insulating layer on a first substrate including first chip regions and a first scribe lane region disposed between the first chip regions; forming a first bonding via and a first dummy bonding via in the first interlayer insulating layer, the first bonding via being disposed in the first chip regions, and the first dummy bonding via being disposed in the first scribe lane region; forming a first bonding pad surrounding a portion of a sidewall of the first bonding via; forming a first dummy hole by removing the first dummy bonding via; and forming a first dummy insulating pillar in the first dummy hole.

These and other features and advantages of the embodiments of the present disclosure will become better understood from the detailed description in conjunction with the following drawings.

### BRIEF DESCRIPTION OF THE DRAWINGS

FIGS. 1A and 1B are simplified schematic diagrams describing a semiconductor device in accordance with an embodiment of the present disclosure.

FIG. 2 is a simplified schematic diagram describing a semiconductor device in accordance with an embodiment of the present disclosure.

FIGS. 3A to 3E are simplified schematic diagrams describing a manufacturing method of a semiconductor device in accordance with an embodiment of the present disclosure.

FIGS. 4A, 5A, and 6A and FIGS. 4B, 5B and 6B are simplified schematic diagrams describing a manufacturing method of a semiconductor device in accordance with an embodiment of the present disclosure.

FIGS. 7A to 7C are simplified schematic diagrams describing a manufacturing method of a semiconductor device in accordance with an embodiment of the present disclosure.

### DETAILED DESCRIPTION

Various embodiments of the present disclosure are directed to a semiconductor device having a stable structure and improved characteristics and a manufacturing method of the semiconductor device.

According to the embodiments, it is possible to provide a semiconductor device having a stable structure, improved reliability, and which prevents the occurrence of the delamination phenomenon. Delamination is a critical issue in semiconductor manufacturing and operation that involves the separation of layers within a device. It can be caused by thermal and mechanical stresses, moisture, poor adhesion, and material incompatibility. Detection and prevention are essential to ensure the reliability and longevity of semiconductor devices.

Hereafter, embodiments in accordance with the technical spirit of the present disclosure will be described with reference to the accompanying drawings.

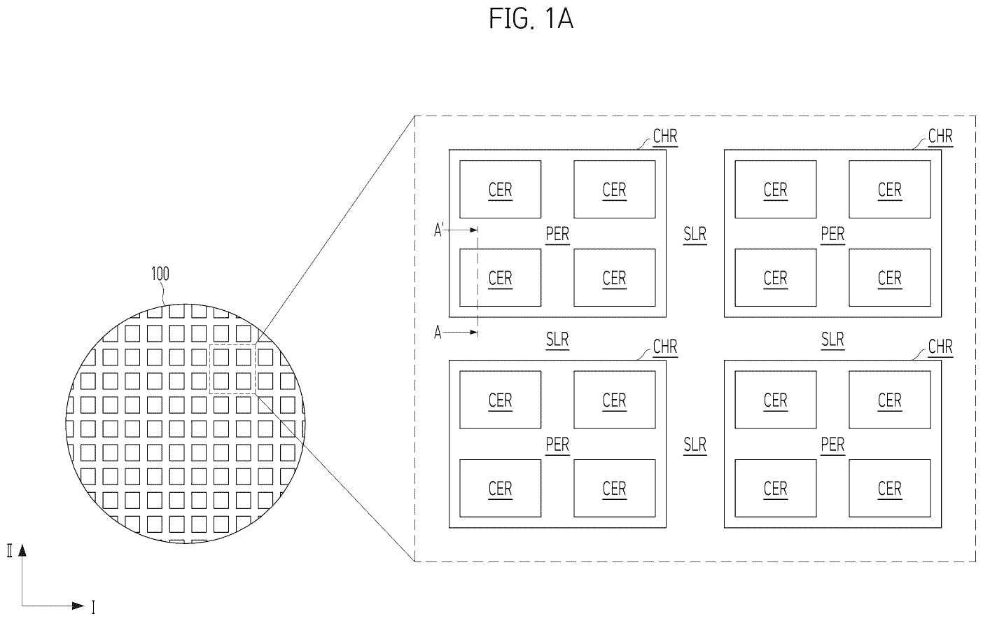

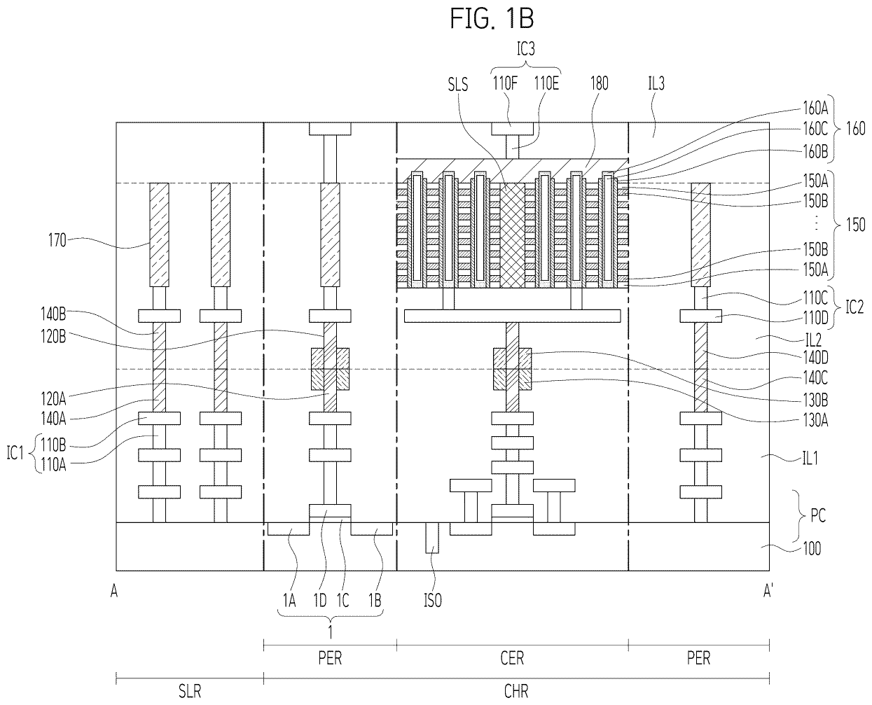

FIGS. 1A and 1B are simplified schematic diagrams describing a semiconductor device in accordance with an embodiment of the present disclosure. FIG. 1A may be a plan view, and FIG. 1B may be a cross-sectional view taken along line A-A′ of FIG. 1A.

Referring to FIG. 1A, the semiconductor device may include a substrate 100. The substrate 100 may include a plurality of chip regions CHR and a scribe lane region SLR surrounding the chip regions CHR. The chip regions CHR are regions where semiconductor chips are formed. The semiconductor chips may be repeatedly formed on the substrate 100. The chip regions CHR may be arranged in a first direction I and a second direction II intersecting the first direction I. The first and second directions I and II may be perpendicular to each other. The scribe lane region SLR may be disposed between and around the chip regions CHR. The scribe lane region SLR may be a region where test patterns for testing the semiconductor chips or alignment key patterns are formed. In addition, the scribe lane region SLR may be a region cut out in a dicing process for separating the semiconductor chips from each other. The chip regions CHR may be separated from each other by cutting the substrate 100 along the scribe lane region SLR.

Each of the chip regions CHR may include a plurality of cell regions CER and a peripheral circuit region PER disposed between and around the individual cell regions CER. Here, the cell regions CER may be regions where cell arrays CA each including a gate structure, channel structures, a source structure, or the like, are formed. The cell regions CER may be arranged in the first direction I and the second direction II. The peripheral circuit region PER may surround the cell regions CER. The peripheral circuit region PER may be a region where peripheral circuits for driving the cell arrays CA are formed. The peripheral circuit region PER may include a center region and an edge region. The peripheral circuits may be more concentrated in the center region than in the edge region.

Referring to FIG. 1B, the semiconductor device may include at least one of the substrate 100, a peripheral circuit PC, first to third interlayer insulating layers IL1, IL2, IL3, first to third interconnection structures IC1, IC2, a third interconnection structure IC3, first and second bonding vias 120A, 120B, first and second bonding pads 130A, 130B, first to fourth dummy insulating pillars 140A, 140B, 140C, 140D, a gate structure 150, a plurality of channel structures 160, a plurality of contact plugs 170, a source structure 180, and a slit structure SLS.

The peripheral circuit PC may be disposed on or over the substrate 100. For example, the peripheral circuit PC may include at least one transistor 1 including junctions 1A and 1B, a gate electrode 1D, and a gate insulating layer 1C. The gate insulating layer 1C may be disposed between the gate electrode 1D and the substrate 100. An element isolation layer ISO may be disposed in the substrate 100 defining an active region for the transistor 1.

The first interconnection structure IC1 may be disposed on or over the substrate 100. The first interconnection structure IC1 may be disposed in the first interlayer insulating layer IL1. The first interlayer insulating layer IL1 may be disposed on the substrate 100. For example, the first interlayer insulating layer IL1 may be disposed in the chip regions CHR and the scribe lane region SLR of the substrate 100. The first interconnection structure IC1 may include first vias 110A extending in a direction perpendicular to the substrate 100 and first wiring lines 110B extending in a direction parallel to the substrate.

The first interconnection structure IC1 may be connected to the peripheral circuit PC. For example, at least one of the first vias 110A may be connected to the transistor 1. At least one of the first vias 110A may connect the first wiring lines 110B to each other. The first interconnection structure IC1 may contact the substrate 100. For example, at least one of the first vias 110A may contact the substrate 100. The first wiring lines 110B may connect the first vias 110A to each other. The first interconnection structure IC1 may include a suitable conductive material such as, for example, tungsten, copper, or aluminum. The first interlayer insulating layer IL1 may include a suitable insulating material such as, for example, an oxide or a nitride.

The first bonding pads 130A may be disposed on or over the substrate 100. The first bonding pads 130 may be disposed in the first interlayer insulating layer IL1 in the chip regions CHR. For example, the first bonding pads 130A may be disposed in the cell regions CER. The first bonding pads 130A may be connected to the peripheral circuit PC through the first interconnection structure IC1. The first bonding pads 130A may not exist in the scribe lane region SLR. The scribe lane region SLR may be free of any first bonding pads 130A. The first bonding pads 130A may each include a suitable conductive material such as, for example, copper.

The second bonding pads 130B may be disposed on or over the first bonding pads 130A. The second bonding pads 130B may contact the first bonding pads 130A. For example, the second bonding pads 130B may be disposed in the cell regions CHR, and may be connected to the first bonding pads 130A. The second bonding pads 130B may not exist in the scribe lane region SLR. The scribe lane region SLR may be free of any second bonding pads 130B. The second bonding pads 130B may be disposed in the second interlayer insulating layer IL2. The second interlayer insulating layer IL2 may be disposed on the first interlayer insulating layer IL1. The second bonding pads 130B may each include a suitable conductive material such as, for example, copper. The second interlayer insulating layer IL2 may include a suitable insulating material such as an oxide or a nitride.

The first bonding vias 120A may be disposed in the cell region CER and/or peripheral circuit region PER. For example, the first bonding vias 120A may penetrate through the first bonding pads 130A, and may penetrate through the first bonding pads 130A and be connected to the first interconnection structure IC1. The first bonding vias 120A may each include a suitable conductive material such as tungsten.

The second bonding vias 120B may be disposed in the cell region CER and/or peripheral circuit region PER. For example, the second bonding vias 120B may penetrate through the second bonding pads 130B, and may penetrate through the second bonding pads 130B and be connected to the first bonding vias 120A. The second bonding vias 120B may each include a suitable conductive material such as tungsten.

In a process of manufacturing the semiconductor device, the first bonding pads 130A and the second bonding pads 130B may be bonded to each other. The first bonding pads 130A and the second bonding pads 130B may each include copper, and the first bonding pads 130A and the second bonding pads 130B expand in a bonding process, such that a delamination phenomenon may occur at a bonding interface.

Bonding force at the bonding interface may become greater as an area occupied by the first interlayer insulating layer IL1 and the second interlayer insulating layer IL2 becomes greater. For example, the bonding force at the bonding interface may become greater as the area occupied by the first interlayer insulating layer IL1 and the second interlayer insulating layer IL2 becomes greater than an area occupied by the first bonding pads 130A and the second bonding pads 130B.

According to an embodiment of the present disclosure, the first bonding pads 130A and the second bonding pads 130B might not exist in the scribe lane region SLR. The area occupied by the first interlayer insulating layer IL1 and the second interlayer insulating layer IL2 in the scribe lane region SLR may be relatively greater than that in the chip region CHR, and the bonding force at the bonding interface in the scribe lane region SLR may be relatively greater than that in the chip region CHR. Advantageously, even though the first bonding pads 130A and the second bonding pads 130B expand in the chip region CHR, the delamination phenomenon might not occur at the bonding interface.

The first dummy insulating pillar 140A may be disposed in the scribe lane region SLR. For example, the first dummy insulating pillar 140A may be disposed in a region where the test patterns or the alignment key patterns are not formed, in the scribe lane region SLR. Here, the first dummy insulating pillar 140A may extend through the first interlayer insulating layer IL1. The first dummy insulating pillar 140A may be disposed at a level corresponding to the first bonding via 120A. The first dummy insulating pillar 140A may include a different material from the first bonding via 120A. The first dummy insulating pillar 140A may include a suitable insulating material. For example, the first dummy insulating pillar 140A may include a suitable insulating material such as an oxide or a nitride.

The second dummy insulating pillar 140B may be disposed in the scribe lane region SLR. For example, the second dummy insulating pillar 140B may be disposed in a region that is free of any test patterns or alignment key patterns, in the scribe lane region SLR. The second dummy insulating pillar 140B may extend through the second interlayer insulating layer IL2 and may be connected to the first dummy insulating pillar 140A. The second dummy insulating pillar 140B may be disposed at a level corresponding to the second bonding via 120B. The second dummy insulating pillar 140B and the second bonding via 120B may be co-extensive in the stacking direction. The second dummy insulating pillar 140B may include a different material from the second bonding via 120B. The second dummy insulating pillar 140B may include a suitable insulating material. For example, the second dummy insulating pillar 140B may include a suitable insulating material such as an oxide or a nitride.

The third dummy insulating pillar 140C may be disposed in the peripheral circuit region PER. The third dummy insulating pillar 140C may be disposed at a level corresponding to the first dummy insulating pillar 140A, in the peripheral circuit region PER. The third dummy insulating pillar 140C may be disposed in a region where the peripheral circuits PC are not concentrated, in the peripheral circuit region PER. For example, the third dummy insulating pillar 140C may be disposed in a region where the first bonding pads 130A do not exist. The third dummy insulating pillar 140C may extend through the first interlayer insulating layer IL1. The third dummy insulating pillar 140C may include substantially the same material as the first dummy insulating pillar 140A. For example, the third dummy insulating pillar 140C may include a suitable insulating material such as an oxide or a nitride.

The fourth dummy insulating pillar 140D may be disposed in the peripheral circuit region PER. The fourth dummy insulating pillar 140D may be disposed at a level corresponding to the second dummy insulating pillar 140B. The fourth dummy insulating pillar 140D may be disposed in a region where the peripheral circuits PC are not concentrated, in the peripheral circuit region PER. The fourth dummy insulating pillar 140D may extend through the second interlayer insulating layer IL2 and be connected to the third dummy insulating pillar 140C. The fourth dummy insulating pillar 140D may include substantially the same material as the second dummy insulating pillar 140B. For example, the fourth dummy insulating pillar 140D may include a suitable insulating material such as an oxide or a nitride.

In a process of bonding the first bonding pads 130A and the second bonding pads 130B to each other, the first dummy insulating pillar 140A and the second dummy insulating pillar 140B may be connected to each other, and the third dummy insulating pillar 140C and the fourth dummy insulating pillar 140D may be connected to each other. The first dummy insulating pillar 140A, the second dummy insulating pillar 140B, the third dummy insulating pillar 140C, and the fourth dummy insulating pillar 140D may be disposed in a region where the first bonding pads 130A and the second bonding pads 130B are not formed. Because bonding pads do not exist at a bonding interface between the first dummy insulating pillar 140A and the second dummy insulating pillar 140B and a bonding interface between the third dummy insulating pillar 140C and the fourth dummy insulating pillar 140D, expansion might not occur. Beneficially, it is possible to prevent or minimize the occurrence of a delamination phenomenon at the bonding interface.

The first dummy insulating pillar 140A, the second dummy insulating pillar 140B, the third dummy insulating pillar 140C, and the fourth dummy insulating pillar 140D may replace dummy bonding vias in a manufacturing process. The dummy bonding vias may each include tungsten. In the process of manufacturing the semiconductor device, tungsten may be oxidized to form an oxide layer. In such a case, a delamination phenomenon may occur at a bonding interface between the dummy bonding vias in a bonding process. Accordingly, to prevent the delamination phenomenon, the dummy bonding vias may be replaced with the first dummy insulating pillar 140A, the second dummy insulating pillar 140B, the third dummy insulating pillar 140C, and the fourth dummy insulating pillar 140D. Here, the dummy bonding vias may be used as a planarization barrier in a process of forming the first bonding pads 130A and the second bonding pads 130B.

The second interconnection structure IC2 may be disposed on or over the first interconnection structure IC1. The second interconnection structure IC2 may be disposed in the second interlayer insulating layer IL2. The second interconnection structure IC2 may include second vias 110C and second wiring lines 110D. At least one of the second vias 110C may be connected to the channel structures 160. At least one of the second vias 110C may be connected to the contact plug 170. The second wiring lines 110D may be connected to at least one of the second vias 110C. The second interconnection structure IC2 may include a suitable conductive material such as tungsten, copper, or aluminum.

The gate structure 150 may be disposed in the chip regions CHR. For example, the gate structure 150 may be disposed in the cell regions CER, and may be disposed on or over the second bonding vias 120B. The gate structure 150 may include insulating layers 150A and conductive layers 150B that are alternately stacked. The insulating layers 150A may each include a suitable insulating material such as, for example, an oxide. The conductive layers 150B may each include a suitable conductive material such as tungsten, polysilicon, or molybdenum. The channel structures 160 may extend through the gate structure 150. Each of the channel structures 160 may include at least one of a channel layer 160A, a memory layer 160B surrounding the channel layer 160A, and an insulating core 160C disposed in the channel layer 160A. The slit structure SLS may extend through the gate structure 150. The slit structure SLS may include a suitable insulating material, a suitable conductive material, a semiconductor material, or the like.

The conductive layers 150B may be gate lines such as source select lines, word lines, or drain select lines. Source select transistors, memory cells, or drain select transistors may be disposed in regions where the channel structures 160 and the conductive layers 150B intersect each other. As an example, at least one source select transistor, a plurality of memory cells, and at least one drain select transistor that are stacked along the channel structure 160 may constitute one memory string.

The contact plug 170 may be disposed on or over the peripheral circuit PC. In addition, the contact plug 170 may be disposed in the scribe lane region SLR. The contact plug 170 may be disposed in the second interlayer insulating layer IL2. The contact plug 170 may be electrically connected to the peripheral circuit PC. For example, the contact plug 170 may be electrically connected to the peripheral circuit PC through the second bonding via 120B, the first bonding via 120A, the second bonding pad 130B, and the first bonding pad 130A. The contact plug 170 may include a suitable conductive material such as tungsten, copper, or aluminum.

The source structure 180 may be disposed on or over the gate structure 150. The source structure 180 may be connected to the channel structures 160. For example, the source structure 180 may be connected to the channel layers 160A of the channel structures 160. The source structure 180 may constitute the cell array CA together with the channel structures 160 and the like.

The third interconnection structure IC3 may be disposed on or over the second interconnection structure IC2. The third interconnection structure IC3 may be disposed in the third interlayer insulating layer IL3. Here, the third interlayer insulating layer IL3 may be disposed on the second interlayer insulating layer IL2, and may include a suitable insulating material such as an oxide or a nitride. The third interconnection structure IC3 may include third vias 110E and third wiring lines 110F. At least one of the third vias 110E may be connected to the contact plug 170. For example, the third via 110E may be connected to the contact plug 170 electrically connected to the peripheral circuit PC, and might not be connected to the contact plug 170 connected to the second dummy insulating pillar 140B or the fourth dummy insulating pillar 140D. At least one of the third vias 110E may be connected to the source structure 180. The third wiring lines 110F may be connected to at least one of the third vias 110E. The third interconnection structure IC3 may include a suitable conductive material such as tungsten, copper, or aluminum.

According to the structure described above, the first bonding via 120A, the second bonding via 120B, the first bonding pad 130A, and the second bonding pad 130B for electrically connecting the cell array CA and the peripheral circuit PC to each other may be disposed in the chip regions CHR. The first bonding pad 130A and the second bonding pad 130B may be disposed to correspond to the first bonding via 120A and the second bonding via 120B, respectively. For example, in the center region where the peripheral circuits PC are concentrated in the peripheral circuit region PER, the first bonding via 120A, the second bonding via 120B, the first bonding pad 130A, and the second bonding pad 130B may be disposed.

In addition, the third dummy insulating pillar 140C and the

fourth dummy insulating pillar 140D for preventing the occurrence of the delamination phenomenon at the bonding interface may be disposed in the chip regions CHR. For example, the third and the fourth dummy insulating pillars 140C and 140D may be disposed in the edge region where the peripheral circuits PC are not concentrated.

The first and second dummy insulating pillars 140A and 140B may be disposed in the scribe lane region SLR. The first and second dummy insulating pillars 140A and 140B may prevent the occurrence of the delamination phenomenon at the bonding interface.

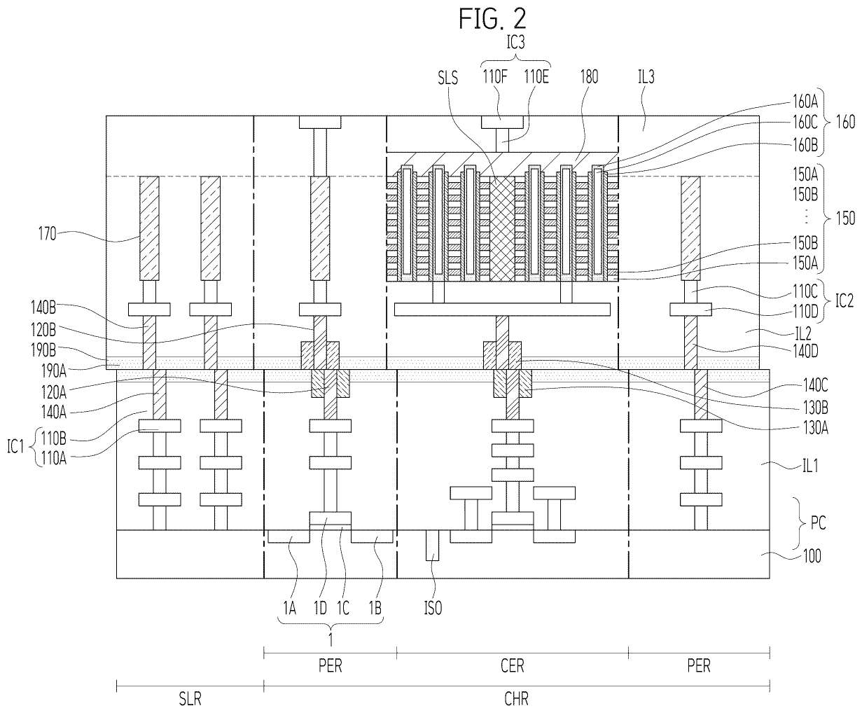

FIG. 2 is a simplified schematic diagram describing a semiconductor device in accordance with an embodiment of the present disclosure. Hereinafter, any content overlapping with previously described content may be omitted.

Referring to FIG. 2, the semiconductor device may include a substrate 100, a peripheral circuit PC, a first interlayer insulating layer IL1, a second interlayer insulating layer IL2, a third interlayer insulating layer IL3, a first interconnection structure IC1, a second interconnection structure IC2, a third interconnection structure IC3, a first bonding via 120A, a second bonding via 120B, a first bonding pad 130A, a second bonding pad 130B, a first dummy insulating pillar 140A, a second dummy insulating pillar 140B, a third dummy insulating pillar 140C, a fourth dummy insulating pillar 140D, a gate structure 150, a channel structure 160, a contact plug 170, a source structure 180, and a slit structure SLS. The semiconductor device may further include at least one of a first bonding layer 190A and a second bonding layer 190B.

The first bonding layer 190A may be disposed on or over the first interlayer insulating layer IL1. The second bonding layer 190B may be disposed between the first bonding layer 190A and the second interlayer insulating layer IL2. The second bonding layer 190B may be connected to the first bonding layer 190A. At least one of the first bonding via 120A, the first bonding pad 130A, the first dummy insulating pillar 140A, and the third dummy insulating pillar 140C may penetrate through the first bonding layer 190A. At least one of the second bonding via 120B, the second bonding pad 130B, the second dummy insulating pillar 140B, and the fourth dummy insulating pillar 140D may penetrate through the second bonding layer 190B.

The first bonding layer 190A and the second bonding layer 190B may each include substantially the same material as or a different material from the first interlayer insulating layer IL1 and the second interlayer insulating layer IL2. For example, the first bonding layer 190A and the second bonding layer 190B may each include nitride, and the first interlayer insulating layer IL1 and the second interlayer insulating layer IL2 may each include oxide.

The first interlayer insulating layer IL1 and the second interlayer insulating layer IL2 may each have first stress, and the first bonding layer 190A and the second bonding layer 190B may each have second stress of a different type from the first stress. The “stress” refers to the intrinsic mechanical stress present in a layer after it has been formed. The stress may be tensile or compressive type. For example, the first bonding layer 190A and the second bonding layer 190B may each have the second stress offsetting the first stress. When the first interlayer insulating layer IL1 and the second interlayer insulating layer IL2 each include oxide, tensile stress may act on the wafers. In such a case, warpage of the wafers may occur. When the first bonding layer 190A and the second bonding layer 190B each include nitride, compressive stress may act on the wafers. In such a case, the tensile stress and the compressive stress may be offset, and the warpage may be improved.

In a process of manufacturing a semiconductor device, the first bonding layer 190A may be formed on or over the first interlayer insulating layer IL1, and the second bonding layer 190B may be formed on or over the second interlayer insulating layer IL2. The occurrence of the warpage may be prevented or minimized by offsetting the tensile stress and the compressive stress acting on the respective wafers. In addition, when the first bonding layer 190A and the second bonding layer 190B each include nitride, bonding force at a bonding interface between the first bonding layer 190A and the second bonding layer 190B may increase. The first bonding layer 190A may have a relatively smaller thickness than the first interlayer insulating layer IL1, and the second bonding layer 190B may have a relatively smaller thickness than the second interlayer insulating layer IL2.

In the process of manufacturing the semiconductor device, the first bonding pads 130A and the second bonding pads 130B may not be aligned with each other. For example, a partial region of the first bonding pad 130A may contact the second bonding pad 130B, and the remaining region of the first bonding pad 130A may contact the second bonding layer 190B. A partial region of the second bonding pad 130B may contact the first bonding pad 130A, and the remaining region of the second bonding pad 130B may contact the first bonding layer 190A. In such a case, in a bonding process, the first bonding pads 130A may expand into the second bonding layer 190B, and the second bonding pads 130B may expand into the first bonding layer 190A.

When the first bonding pads 130A and the second bonding pads 130B are aligned with each other, the first bonding pads 130A and the second bonding pads 130B may push each other while expanding in the bonding process, and a delamination phenomenon may occur at a bonding interface. According to an embodiment of the present disclosure, the first bonding pads 130A and the second bonding pads 130B might not be aligned with each other. Accordingly, contact areas between the first bonding pads 130A and the second bonding pads 130B may become smaller than those when the first bonding pads 130A and the second bonding pads 130B are aligned with each other, and it is thus possible to prevent or reduce the occurrence of the delamination phenomenon at the bonding interface.

For reference, it has been described in the present disclosure that when the first bonding layer 190A and the second bonding layer 190B exist, the first bonding pads 130A and the second bonding pads 130B are not aligned with each other, but the first bonding layer 190A and the second bonding layer 190B may be omitted. In such a case, in the bonding process, portions of the first bonding pads 130A may expand into the second interlayer insulating layer IL2, and portions of the second bonding pads 130B may expand into the first interlayer insulating layer IL1.

In addition, the first bonding via 120A and the second bonding via 120B may or may not be connected to each other. Here, the first dummy insulating pillar 140A and the second dummy insulating pillar 140B may not be connected to each other, and the third dummy insulating pillar 140C and the fourth dummy insulating pillar 140D might not be connected to each other. Even though the first bonding via 120A and the second bonding via 120B are not connected to each other, the first bonding pad 130A and the second bonding pad 130B are connected to each other, such that the first bonding via 120A and the second bonding via 120B may be electrically connected to each other.

According to the structure described above, the semiconductor device may also include the first bonding layer 190A and the second bonding layer 190B. In such a case, the bonding force at the bonding interface between the first bonding layer 190A and the second bonding layer 190B may increase. In addition, the stress of the first interlayer insulating layer IL1 may be offset by the first bonding layer 190A, and the stress of the second interlayer insulating layer IL2 may be offset by the second bonding layer 190B. Through this, the warpage of the wafer may be improved. In addition, when the first bonding layer 190A and the second bonding layer 190B each include nitride, the bonding force at the bonding interface between the first bonding layer 190A and the second bonding layer 190B may increase.

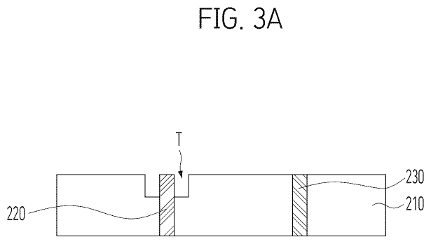

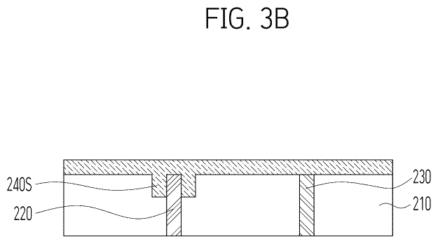

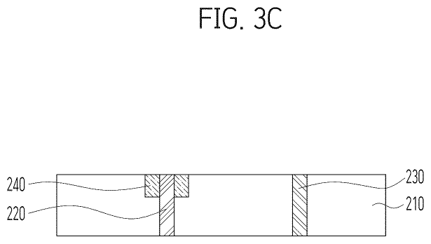

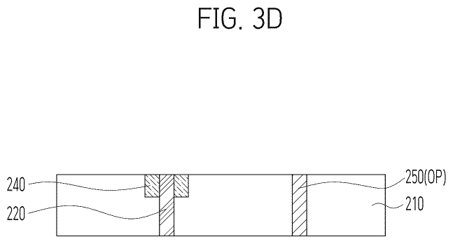

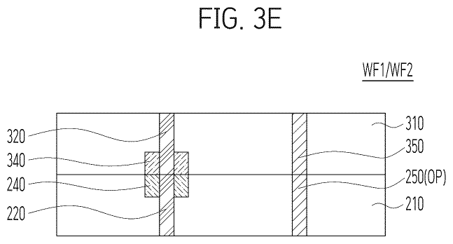

FIGS. 3A to 3E are simplified schematic diagrams describing a manufacturing method of a semiconductor device in accordance with an embodiment of the present disclosure. Hereinafter, any content overlapping with previously described content may be omitted.

Referring now to FIG. 3A, a first interlayer insulating layer 210 may be formed on a substrate (not illustrated). The first interlayer insulating layer 210 may include a suitable insulating material such as an oxide or a nitride.

Subsequently, a first bonding via 220 and a first dummy bonding via 230 may be formed to extend through the first interlayer insulating layer 210. When the first bonding via 220 is formed, the first dummy bonding via 230 may be formed also at the same time. The first bonding via 220 and the first dummy bonding via 230 may each include a suitable conductive material such as tungsten.

Subsequently, a trench T exposing portions of sidewalls of the first bonding via 220 may be formed. Here, only portions of the sidewalls of the first bonding via 220 may be exposed. The sidewalls of the first dummy bonding via 230 may not be exposed.

Referring to FIG. 3B, a preliminary bonding pad 240S filling the trench T may be formed. The preliminary bonding pad 240S may also be formed on or over the first interlayer insulating layer 210. The preliminary bonding pad 240S may include a suitable conductive material such as, for example, copper.

Referring to FIG. 3C, a first bonding pad 240 may be formed in the trench T. For example, the first bonding pad 240 may be formed by planarizing the preliminary bonding pad 240S until the first interlayer insulating layer 210 is exposed. The first bonding via 220 and the first dummy bonding via 230 may be used as a planarization barrier. For example, the preliminary bonding pad 240S may be etched until the first bonding via 220 and the first dummy bonding via 230 are exposed. According to an embodiment of the present disclosure, the occurrence of dishing which may negatively impact surface planarity, electrical performance, and device reliability, may be advantageously prevented or minimized by using the first bonding via 220 and the first dummy bonding via 230 as the planarization barrier in a planarization process. Hence, a non-uniform surface, non-flat surface may be avoided and high-quality wafer surfaces may be ensured.

Referring to FIG. 3D, a dummy hole OP may be formed by selectively removing the first dummy bonding via 230, for example, through a wet etching process. Subsequently, a first dummy insulating pillar 250 may be formed in the dummy hole OP by filling the dummy hole OP with a suitable insulating material such as an oxide or a nitride. The forming of the first dummy insulating pillar 250 in the dummy hole OP may be performed, for example, with a deposition process.

Referring to FIG. 3E, a first wafer WF1 and a second wafer may be bonded to each other. The first wafer WF1 may include the first interlayer insulating layer 210, the first bonding via 220, the first bonding pad 240, and the first dummy insulating pillar 250. The second wafer WF2 may include a second interlayer insulating layer 310, a second bonding via 320, a second bonding pad 340, and a second dummy insulating pillar 350.

Here, the first wafer WF1 and the second wafer WF2 may be bonded to each other so that the first bonding via 220 and the second bonding via 320 face each other, the first bonding pad 240 and the second bonding pad 340 face each other, and the first dummy insulating pillar 250 and the second dummy insulating pillar 350 face each other. Hence, the first and second wafers WF1, WF2 are bonded and the first bonding via 220 is aligned with the second bonding via 320, the first bonding pad 240 is aligned with the second bonding pad 340, and the first dummy insulating pillar 250 is aligned with the second dummy insulating pillar 350. The alignment of these features is in the stacking direction.

In the bonding process of the first wafer WF1 with the second wafer WF2, the first bonding pad 240 and the second bonding pad 340 may expand, such that a delamination phenomenon may occur at a bonding interface. Bonding force at the bonding interface may become greater as an area occupied by the first interlayer insulating layer 210 and the second interlayer insulating layer 310 becomes greater. For example, the bonding force at the bonding interface may become greater as the area occupied by the first interlayer insulating layer 210 and the second interlayer insulating layer 310 becomes greater than an area occupied by the first bonding pads 240 and the second bonding pads 340.

According to an embodiment of the present disclosure, the first bonding pads 240 and the second bonding pads 340 may not be formed in a region where the first dummy bonding via 230 and a second dummy bonding via (not illustrated) are formed. In such a case, the area occupied by the first interlayer insulating layer 210 and the second interlayer insulating layer 310 may be relatively great, and the bonding force at the bonding interface may become great. Accordingly, the delamination phenomenon might not occur at the bonding interface even though the first bonding pads 240 and the second bonding pads 340 expand.

In addition, the first dummy bonding via 230 and the second dummy bonding via may be removed after being used as planarization barriers, and may be replaced with the first dummy insulating pillar 250 and the second dummy insulating pillar 350, respectively. When the first dummy bonding via 230 and the second dummy bonding via (not shown) are not removed, the first dummy bonding via 230 and the second dummy bonding via may be oxidized to form oxide layers, and the oxide layers may protrude from surfaces of the first interlayer insulating layer 210 and the second interlayer insulating layer 310. In such a case, a delamination phenomenon may occur while a protruding portion of the first dummy bonding via 230 of the first wafer WF1 and a protruding portion of the second dummy bonding via of the second wafer WF2 are bonded to each other in a bonding process of a subsequent process. However, according to an embodiment of the present disclosure, the first dummy bonding via 230 and the second dummy bonding via may be replaced with the first dummy insulating pillar 250 and the second dummy insulating pillar 350, respectively, and the occurrence of the delamination phenomenon in the bonding process may be prevented or minimized.

According to the manufacturing method described above, in a process of manufacturing the first bonding pads 240 and the second bonding pads 340, the first bonding via 220, the first dummy bonding via 230, the second bonding via 320 and the second dummy bonding via may be used as the planarization barriers.

The first dummy bonding via 230 and the second dummy bonding via may be removed after being used as the planarization barriers. This is because the delamination phenomenon may occur in the bonding process when the first dummy bonding via 230 and the second dummy bonding via are not removed. The first dummy bonding via 230 and the second dummy bonding via may be replaced with the first dummy insulating pillar 250 and the second dummy insulating pillar 350, respectively.

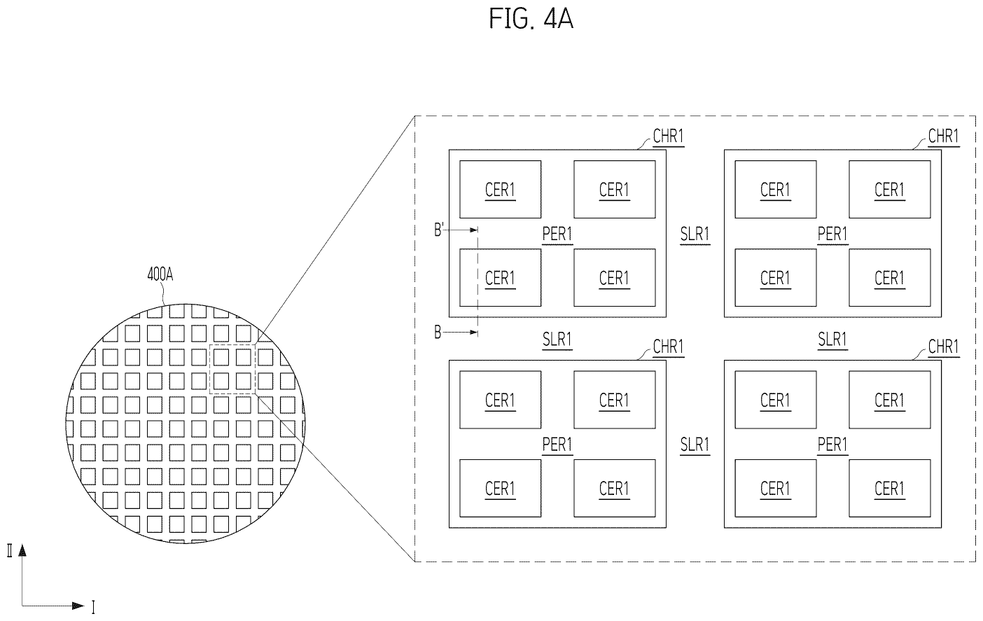

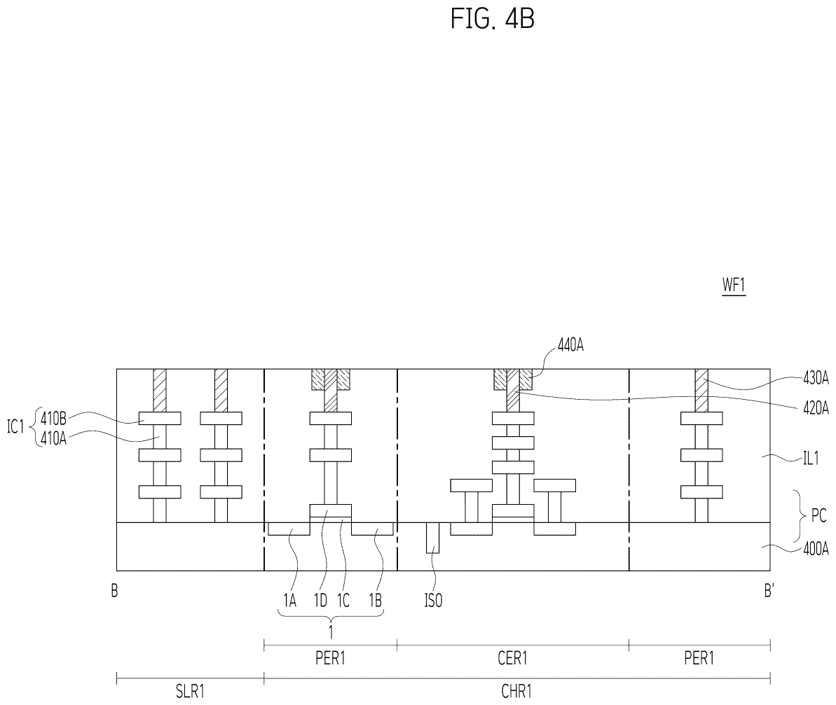

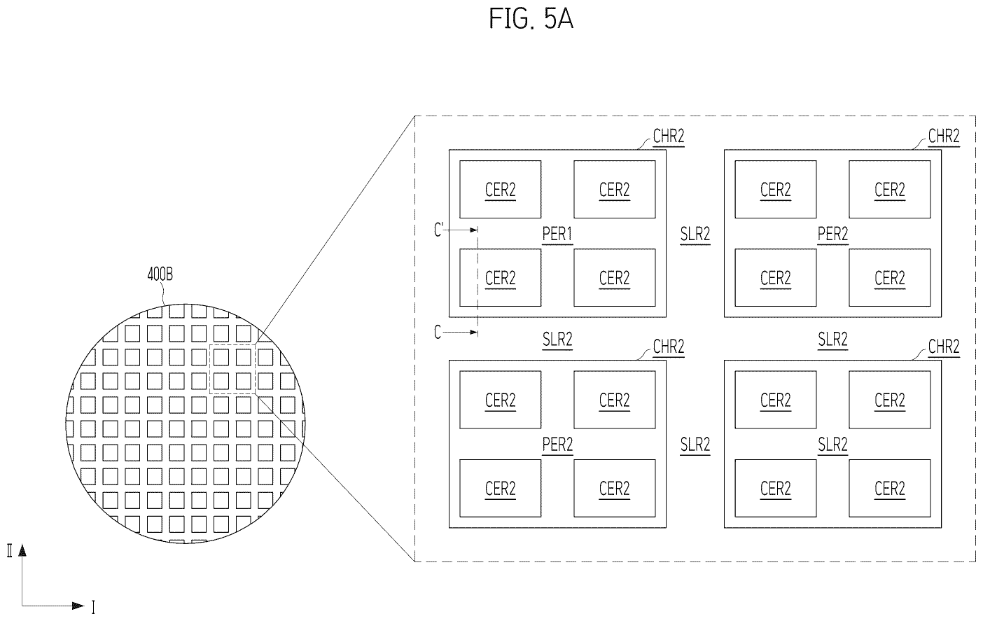

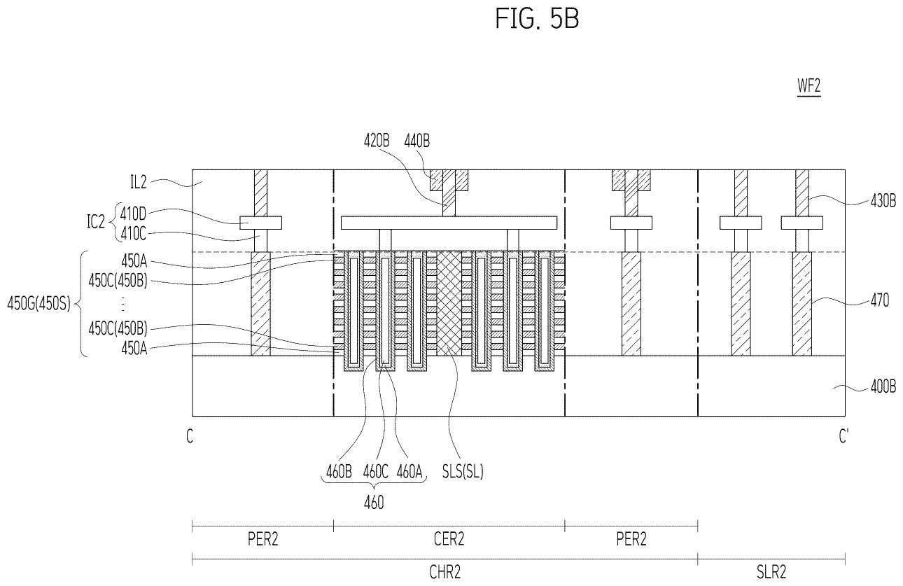

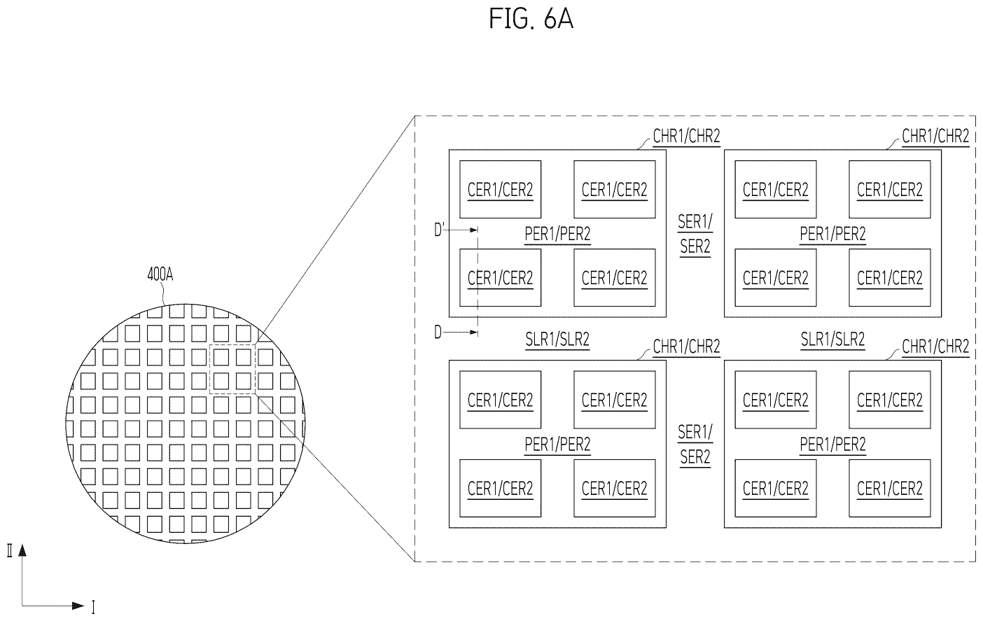

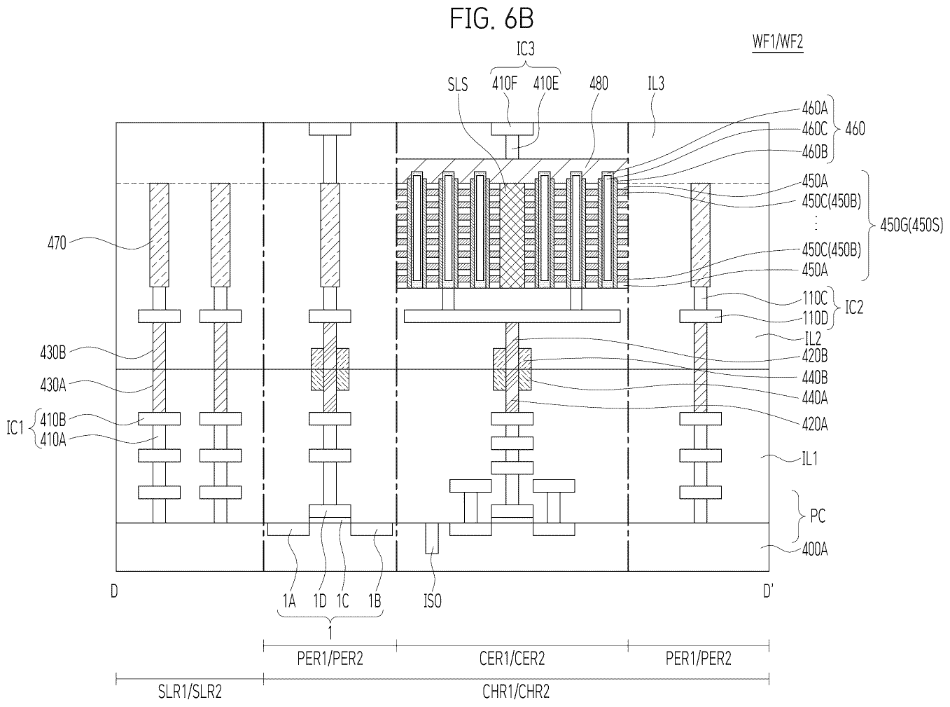

FIGS. 4A, 5A, and 6A and FIGS. 4B, 5B and 6B are simplified schematic diagrams describing a manufacturing method of a semiconductor device in accordance with an embodiment of the present disclosure. FIGS. 4A, 5A, and 6A are plan views, FIG. 4B is a cross-sectional view taken along line B-B′ of FIG. 4A, FIG. 5B is a cross-sectional view taken along line C-C′ of FIG. 5A, and FIG. 6B is a cross-sectional view taken along line D-D′ of FIG. 6A. Hereinafter, any content overlapping with previously described content may be omitted.

Referring to FIGS. 4A and 4B, a peripheral circuit PC may be formed on or over a first substrate 400A which includes first chip regions CHR1 and a first scribe lane region SLR1. The first scribe lane region SLR1 is disposed between the first chip regions CHR1. The first chip regions CHR1 may be regions where semiconductor chips are to be formed. The first scribe lane region SLR1 may be a region where test patterns for testing the semiconductor chips or alignment key patterns are to be formed. In addition, the first scribe lane region SLR1 may be a region cut out in a dicing process for separating the semiconductor chips from each other. Each of the first chip regions CHR1 may include first cell regions CER1 and a first peripheral circuit region PER1 surrounding the first cell regions CER1. The first peripheral circuit region PER1 may include a center region and an edge region. The peripheral circuits PC may be more concentrated in the center region than in the edge region.

The peripheral circuit PC may include at least one transistor 1 including junctions 1A and 1B, a gate electrode 1D, and a gate insulating layer 1C. The gate insulating layer 1C may be formed between the gate electrode 1D and the first substrate 400A. An element isolation layer ISO may be disposed in the first substrate 400A to form an active region of the transistor 1.

A first interconnection structure IC1 may be formed on or over the first substrate 400A. The first interconnection structure IC1 may be formed in a first interlayer insulating layer IL1. The first interlayer insulating layer IL1 may be formed on the first substrate 400A. The first interconnection structure IC1 may be formed in the first chip regions CHR1 and the first scribe lane region SLR1 of the first substrate 400A. The first interconnection structure IC1 may include first vias 410A and first wiring lines 410B. The first interconnection structure IC1 may be connected to the peripheral circuit PC. For example, at least one of the first vias 410A may be connected to the transistor 1. At least one of the first vias 410A may connect the first wiring lines 410B to each other. The first interconnection structure IC1 may contact the first substrate 400A. For example, at least one of the first vias 410A may contact the first substrate 400A. The first wiring lines 410B may connect the first vias 410A to each other. The first interconnection structure IC1 may include a suitable conductive material such as tungsten, copper, or aluminum. The first interlayer insulating layer IL1 may include a suitable insulating material such as an oxide or a nitride.

A first bonding via 420A, a first dummy insulating pillar 430A, and a first bonding pad 440A may be formed in the first interlayer insulating layer IL1. For example, the first bonding via 420A and the first bonding pad 440A may be formed in the first chip regions CHR1. The first bonding via 420A and the first bonding pad 440A may be formed in the first cell regions CER1. The first dummy insulating pillar 430A may be formed in the first scribe lane region SLR1. The first dummy insulating pillar 430A may be disposed in a region where the test patterns or the alignment key patterns are not formed, in the first scribe lane region SLR1. The first dummy insulating pillar 430A may be formed in the first peripheral circuit regions PER1. The first dummy insulating pillar 430A formed in the first peripheral circuit regions PER1 may be defined as a third dummy insulating pillar. The third dummy insulating pillar may be disposed in a region where the peripheral circuits PC are not concentrated, in the first peripheral circuit region PER1. Consequently, a first wafer WF1 including the first substrate 400A, the first interlayer insulating layer IL1, the first bonding via 420A, the first dummy insulating pillar 430A, and the first bonding pad 440A may be formed.

In a method of forming the first bonding via 420A, the first dummy insulating pillar 430A, and the first bonding pad 440A, a method of forming the first bonding via 220, the first dummy insulating pillar 250, and the first bonding pad 240 described with reference to FIGS. 3A to 3D may be utilized. For example, when the first bonding via 420A is formed, a first dummy bonding via (not illustrated) may be formed. Subsequently, the first bonding pad 440A surrounding portions of sidewalls of the first bonding via 420A may be formed. For example, a trench exposing the portions of the sidewalls of the first bonding via 420A may be formed. The first bonding pad 440A may be formed in the trench using the first bonding via 420A and the first dummy bonding via as a planarization barrier. Subsequently, the first dummy insulating pillar 430A may be formed in a first dummy hole formed by removing the first dummy bonding via. Here, the first bonding via 420A may include a suitable conductive material such as tungsten, the first dummy insulating pillar 430A may include a suitable insulating material such as an oxide or a nitride, and the first bonding pad 440A may include a suitable conductive material such as, for example, copper.

Referring to FIGS. 5A and 5B, a gate structure 450G may be formed on or over a second substrate 400B. Here, the second substrate 400B may include second chip regions CHR2 and a second scribe lane region SLR2 disposed between the second chip regions CHR2. Each of the second chip regions CHR2 may include second cell regions CER2 and a second peripheral circuit region PER2 surrounding the second cell regions CER2.

A stack 450S may be formed by alternately stacking first and second material layers 450A and 450B on or over the second substrate 400B For example, the stack 450S may be formed in the second chip regions CHR2. The stack 450S may be formed in the second cell regions CER2. Here, the first material layers 450A may each include a suitable insulating material such as, for example, an oxide and the second material layers 450B may each include a sacrificial material such as nitride. Alternatively, the second material layers 450B may each include a suitable conductive material such as molybdenum. Subsequently, channel structures 460 extending into the second substrate 400B through the stack 450S may be formed. Each of the channel structures 460 may include at least one of a channel layer 460A, a memory layer 460B surrounding the channel layer 460A, and an insulating core 460C disposed in the channel layer 460A.

A slit SL extending through the stack 450S may be formed. Subsequently, the second material layers 450B of the stack 450S may be removed and replaced with third material layers 450C through the slit SL. The third material layers 450C may each include a suitable conductive material such as tungsten, molybdenum, or polysilicon. Consequently, the gate structure 450G may be formed including the first and third material layers 450A, 450C that are alternately stacked. For reference, when the second material layers 450B each include the conductive material, a process of replacing the second material layers 450B with the third material layers 450C may be omitted. Subsequently, a slit structure SLS may be formed in the slit SL. The slit structure SLS may include at least one of an insulating material, a suitable conductive material, and a semiconductor material.

The third material layers 450C may be gate lines such as source select lines, word lines, or drain select lines. Source select transistors, memory cells, or drain select transistors may be disposed in regions where the channel structures 460 and the third material layers 450 intersect each other. As an example, at least one source select transistor, a plurality of memory cells, and at least one drain select transistor that are stacked along the channel structure 460 may constitute one memory string.

A second interlayer insulating layer IL2 may be formed on the second substrate 400B. Contact plugs 470 extending through the second interlayer insulating layer IL2 may be formed. The contact plug 470 may be formed in the second scribe lane region SLR2. The second interlayer insulating layer IL2 may include a suitable insulating material such as an oxide or a nitride. The contact plug 470 may include a suitable conductive material such as tungsten, copper, or aluminum.

A second interconnection structure IC2 may be formed on or over the contact plugs 470 and the gate structure 450G. The second interconnection structure IC2 may be disposed in the second interlayer insulating layer IL2. The second interconnection structure IC2 may include second vias 410C and second wiring lines 410D. At least one of the second vias 410C may be connected to the channel structures 460. At least one of the second vias 410C may be connected to the contact plug 470. The second wiring lines 410D may be connected to at least one of the second vias 410C. The second interconnection structure IC2 may include a suitable conductive material such as tungsten, copper, or aluminum.

A second bonding via 420B, a second dummy insulating pillar 430B, and a second bonding pad 440B may be formed on or over the gate structure 450G. The second bonding via 420B, the second dummy insulating pillar 430B, and the second bonding pad 440B may be formed in the second interlayer insulating layer IL2. For example, the second bonding via 420B and the second bonding pad 440B may be formed in the second chip regions CHR2. The second bonding via 420B and the second bonding pad 440B may be formed in the second cell regions CER2. The second dummy insulating pillar 430B may be formed in the second scribe lane region SLR2. The second dummy insulating pillar 430B may be disposed in a region where test patterns or alignment key patterns are not formed, in the second scribe lane region SLR2. The second dummy insulating pillar 430B may be formed in the second peripheral circuit regions PER2. The second dummy insulating pillar 430B formed in the second peripheral circuit regions PER2 may be defined as a fourth dummy insulating pillar. Consequently, a second wafer WF2 including the second substrate 400B, the second insulating layer IL2, the second bonding via 420B, the second dummy insulating pillar 430B, and the second bonding pad 440B may be formed.

In a method of forming the second bonding via 420B, the second dummy insulating pillar 430B, and the second bonding pad 440B, a method of forming the first bonding via 220, the first dummy insulating pillar 250, and the first bonding pad 240 described with reference to FIGS. 3A to 3D may be utilized. For example, when the second bonding via 420B is formed, a second dummy bonding via (not illustrated) may be formed. Subsequently, the second bonding pad 440B surrounding portions of sidewalls of the second bonding via 420B may be formed. For example, a trench exposing the portions of the sidewalls of the second bonding via 420B may be formed. The second bonding pad 440B may be formed in the trench using the second bonding via 420B and the second dummy bonding via as a planarization barrier. Subsequently, the second dummy insulating pillar 430B may be formed in a second dummy hole formed by removing the second dummy bonding via. Here, the second bonding via 420B may include a suitable conductive material such as tungsten, the second dummy insulating pillar 430B may include a suitable insulating material such as an oxide or a nitride, and the second bonding pad 440B may include a suitable conductive material such as, for example, copper.

Referring to FIGS. 6A and 6B, the first wafer WF1 and the second wafer WF2 may be bonded to each other. For example, the first wafer WF1 and the second wafer WF2 may be bonded to each other so that the first bonding pad 440A and the second bonding pad 440B may be connected to each other, the first bonding via 420A and the second bonding via 420B may be connected to each other, and the first dummy insulating pillar 430A and the second dummy insulating pillar 430B may be connected to each other.

The first bonding pads 440A and the second bonding pads 440B may each include copper, and the first bonding pads 440A and the second bonding pads 440B expand in a process of bonding the first wafer WF1 and the second wafer WF2 to each other, such that a delamination phenomenon may occur at a bonding interface.

Bonding force at the bonding interface may become greater as an area occupied by the first interlayer insulating layer IL1 and the second interlayer insulating layer IL2 becomes greater. For example, the bonding force at the bonding interface may become greater as the area occupied by the first interlayer insulating layer IL1 and the second interlayer insulating layer IL2 becomes greater than an area occupied by the first bonding pads 440A and the second bonding pads 440B.

According to an embodiment of the present disclosure, the first bonding pads 440A might not be formed in the first scribe lane region SLR1, and the second bonding pads 440B might not be formed in the second scribe lane region SLR2. The area occupied by the first interlayer insulating layer IL1 and the second interlayer insulating layer IL2 in the first scribe lane region SLR1 and the second scribe lane region SLR2 may be relatively greater than that in the first chip region CHR1 and the second chip region CHR2, and the bonding force at the bonding interface in the first scribe lane region SLR1 and the second scribe lane region SLR2 may be relatively greater than that in the first chip region CHR1 and the second chip region CHR2. Accordingly, even though the first bonding pads 440A and the second bonding pads 440B expand in the first chip region CHR1 and the second chip region CHR2, the delamination phenomenon might not occur at the bonding interface.

Subsequently, the channel structures 460 may be exposed by removing the second substrate 400B. Subsequently, a source structure 480 connected to the channel structures 460 may be formed. Here, the channel layers 460A of the channel structures 460 and the source structure 480 may be connected to each other.

Subsequently, a third interconnection structure IC3 may be formed in a third interlayer insulating layer IL3. Here, the third interlayer insulating layer IL3 may be formed on the gate structure 450G and the contact plugs 470. The third interconnection structure IC3 may include third vias 410E and third wiring lines 410F. At least one of the third vias 410E may be connected to the contact plug 470. For example, the third via 410E may be connected to the contact plug 470 electrically connected to the peripheral circuit PC, and might not be connected to the contact plug 470 connected to the second dummy insulating pillar 430B. At least one of the third vias 410E may be connected to the source structure 480. The third wiring lines 410F may be connected to at least one of the third vias 410E. The third interconnection structure IC3 may include a suitable conductive material such as tungsten, copper, or aluminum. The third interlayer insulating layer IL3 may include a suitable insulating material such as an oxide or a nitride.

According to the manufacturing method described above, the first bonding via 420A, the first bonding pad 440A, the second bonding via 420B, and the second bonding pad 440B may be formed in the first chip regions CHR1 and the second chip regions CHR2 of the first wafer WF1 and the second wafer WF2. The first dummy insulating pillar 430A and the second dummy insulating pillar 430B for preventing the occurrence of the delamination phenomenon at the bonding interface may be formed in the first chip regions CHR1 and the second chip regions CHR2. For example, the first dummy insulating pillar 430A and the second dummy insulating pillar 430B may be formed in the edge region where the peripheral circuits PC are not concentrated.

Likewise, the first dummy insulating pillar 430A and the second dummy insulating pillar 430B for preventing the occurrence of the delamination phenomenon at the bonding interface may be formed in the first scribe lane region SLR1 and the second scribe lane region SLR2.

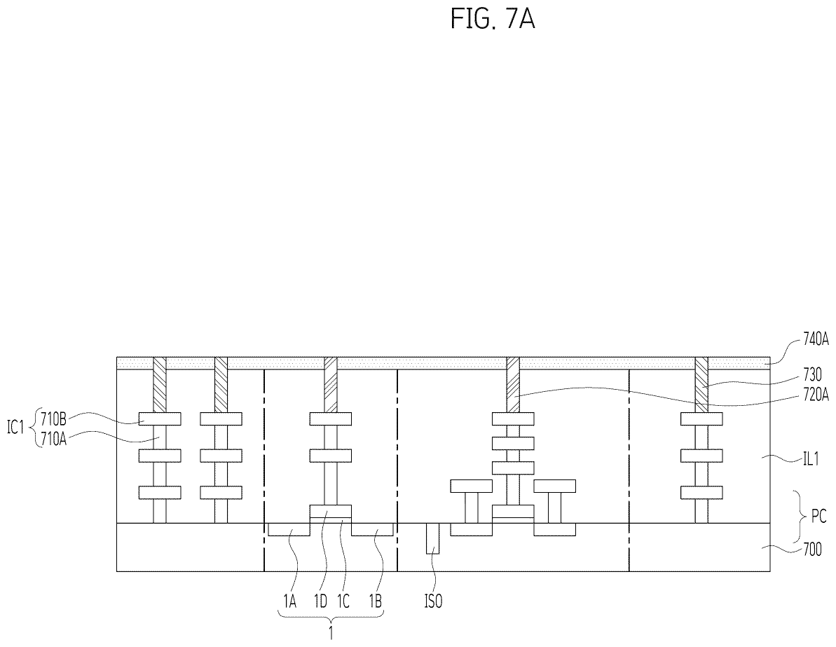

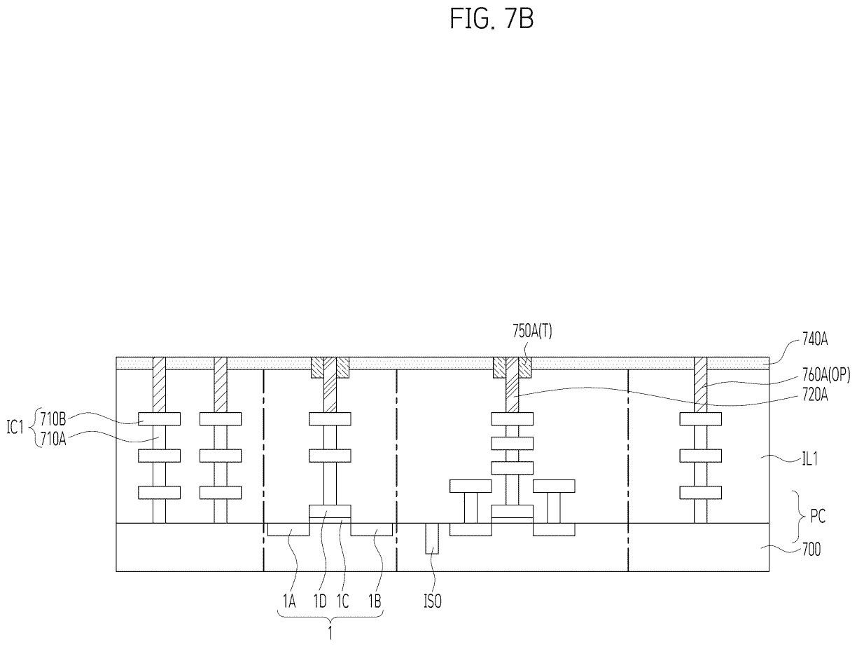

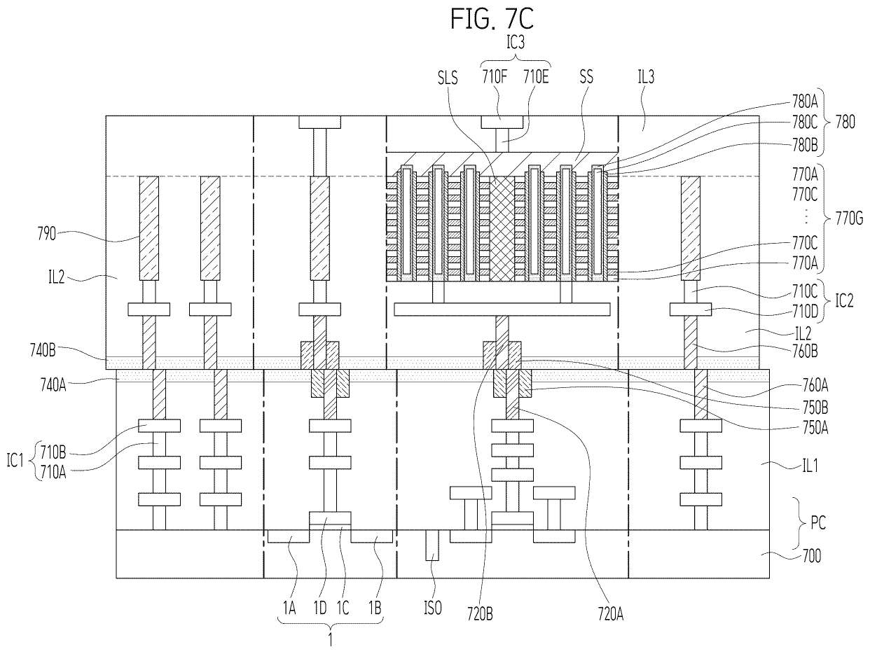

FIGS. 7A to 7C are simplified schematic diagrams describing a manufacturing method of a semiconductor device in accordance with an embodiment of the present disclosure. Hereinafter, any content overlapping with previously described content may be omitted.

Referring to FIG. 7A, a peripheral circuit PC is formed on or over first substrate 700. The peripheral circuit PC includes at least one transistor 1 including junctions 1A and 1B, a gate electrode 1D, and a gate insulating layer 1C formed between the gate electrode 1D and the first substrate 700. An element isolation layer ISO may be disposed in the first substrate 700, and an active region of the transistor 1 may be defined by the element isolation layer ISO.

A first interlayer insulating layer IL1 may be formed on the first substrate 700. A first interconnection structure IC1 may be formed in the first interlayer insulating layer IL1. The first interconnection structure IC1 may include a first via 710A and a first wiring line 710B. The first interconnection structure IC1 may include a suitable conductive material such as tungsten, copper, or aluminum. The first interlayer insulating layer IL1 may include a suitable insulating material such as an oxide or a nitride.

Subsequently, a first bonding layer 740A may be formed on or over the first interlayer insulating layer IL1. The first bonding layer 740A may include substantially the same material as the first interlayer insulating layer IL1. In an embodiment, the first bonding layer 740A may include a different material from the first interlayer insulating layer IL1. For example, the first bonding layer 740A may include a nitride, and the first interlayer insulating layer IL1 may include an oxide.

The first interlayer insulating layer IL1 may have first stress, and the first bonding layer 740A may have second stress of a different type from the first stress. For example, the first bonding layer 740A may have the second stress offsetting the first stress. When the first interlayer insulating layer IL1 includes oxide, tensile stress may act on a wafer. In such a case, warpage of the wafer may occur. When the first bonding layer 740A includes nitride, compressive stress may act on the wafer. In such a case, the tensile stress and the compressive stress may be offset, and the warpage may be improved. Here, the first bonding layer 740A may have a relatively smaller thickness than the first interlayer insulating layer IL1.

In addition, when the first bonding layer 740A includes nitride, bonding force at a bonding interface after a bonding process of a subsequent process may increase. Here, the first bonding layer 740A may have a relatively smaller thickness than the first interlayer insulating layer IL1.

Subsequently, a first bonding via 720A and a first dummy bonding via 730 extending through the first bonding layer 740A may be formed. For example, the first bonding via 720A and the first dummy bonding via 730 extending through the first bonding layer 740A and the first interlayer insulating layer IL1 and connected to the first interconnection structure IC1 may be formed.

Referring to FIG. 7B, a first bonding pad 750A surrounding portions of sidewalls of the first bonding via 720A may be formed. For example, a trench T surrounding the portions of the sidewalls of the first bonding via 720A may be formed, and the first bonding pad 750A may then be formed in the trench T using the first bonding via 720A and the first dummy bonding via 730 as a planarization barrier. The first bonding pad 750A may include a suitable conductive material such as, for example, copper.

Subsequently, a dummy hole OP may be formed by removing the first dummy bonding via 730. For example, the dummy hole OP may be formed by selectively removing the first dummy bonding via 730 through a wet etching process. Subsequently, a first dummy insulating pillar 760A may be formed in the dummy hole OP. Here, the first dummy insulating pillar 760A may include a suitable insulating material such as an oxide or a nitride.

Referring to FIG. 7C, a first wafer and a second wafer may be bonded to each other. The first wafer may include at least one of the first substrate 700, the first interlayer insulating layer IL1, the first bonding via 720A, the first bonding pad 750A, the first dummy insulating pillar 760A, and the first bonding layer 740A. The second wafer may include at least one of a second substrate (not illustrated), a second interlayer insulating layer IL2, a second bonding via 720B, a second bonding pad 750B, a second dummy insulating pillar 760B, a second bonding layer 740B, a gate structure 770G, channel structures 780, contact plugs 790, a second interconnection structure IC2, and a slit structure SLS may be bonded to each other.

The gate structure 770G may include first material layers 770A and third material layers 770C that are alternately stacked. Each of the channel structures 780 may include a channel layer 780A, a memory layer 780B surrounding the channel layer 780A, and an insulating core 780C disposed in the channel layer 780A. The second interconnection structure IC2 may include a second via 710C and a second wiring line 710D.

In a process of bonding the first wafer and the second wafer to each other, the first bonding pads 750A and the second bonding pads 750B might not be aligned with each other. For example, a partial region of the first bonding pad 750A may contact the second bonding pad 750B, and the remaining region of the first bonding pad 750A may contact the second bonding layer 740B. A partial region of the second bonding pad 750B may contact the first bonding pad 750A, and the remaining region of the second bonding pad 750B may contact the first bonding layer 740A.

In such a case, in a bonding process, the first bonding pads 750A may expand into the second bonding layer 740B, and the second bonding pads 750B may expand into the first bonding layer 740A. Thus, contact areas between the first bonding pads 750A and the second bonding pads 750B may become smaller when the first bonding pads 750A and the second bonding pads 750B are not aligned with each other than when the first bonding pads 750A and the second bonding pads 750B are aligned with each other, and it is thus possible to prevent or reduce the occurrence of a delamination phenomenon at the bonding interface.

For example, it has been described in the present disclosure that when the first bonding layer 740A and the second bonding layer 740B exist, the first bonding pads 750A and the second bonding pads 750B are not aligned with each other, however, in this case the first bonding layer 740A and the second bonding layer 740B may be omitted. In such a case, in the bonding process, portions of the first bonding pads 750A may expand into the second interlayer insulating layer IL2, and portions of the second bonding pads 750B may expand into the first interlayer insulating layer IL1.

Subsequently, the channel structures 780 may be exposed by removing the second substrate. Subsequently, a source structure SS connected to the channel layers 780A of the channel structures 780 may be formed. Subsequently, a third interconnection structure IC3 may be formed in a third interlayer insulating layer IL3. Here, the third interlayer insulating layer IL3 may be formed on the gate structure 770G and the contact plugs 790. The third interconnection structure IC3 may include third vias 710E and third wiring lines 710F.

According to the manufacturing method described above, the first bonding layer 740A may be formed on or over the first interlayer insulating layer IL1, and the second bonding layer 740B may be formed on or over the second interlayer insulating layer IL2. In such a case, bonding force at a bonding interface between the first bonding layer 740A and the second bonding layer 740B may increase. In addition, the stress of the first interlayer insulating layer IL1 may be offset by the first bonding layer 740A, and the stress of the second interlayer insulating layer IL2 may be offset by the second bonding layer 740B. Through this, the warpage of the wafer may be improved. In addition, when the first bonding layer 740A and the second bonding layer 740B each include nitride, the bonding force at the bonding interface between the first bonding layer 740A and the second bonding layer 740B may increase.

Although embodiments according to the technical concepts of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a first interlayer insulating layer;
a second interlayer insulating layer disposed on the first interlayer insulating layer;
a first bonding pad disposed in the first interlayer insulating layer;
a second bonding pad disposed in the second interlayer insulating layer and connected to the first bonding pad;
a first bonding via penetrating through the first bonding pad;
a second bonding via penetrating through the second bonding pad and connected to the first bonding via;
a first dummy insulating pillar extending through the first interlayer insulating layer; and
a second dummy insulating pillar extending through the second interlayer insulating layer and connected to the first dummy insulating pillar.

2. The semiconductor device of claim 1, further comprising:
a first bonding layer disposed on the first interlayer insulating layer; and
a second bonding layer disposed between the first bonding layer and the second interlayer insulating layer and connected to the first bonding layer.

3. The semiconductor device of claim 1, further comprising:
a first bonding layer disposed over the first interlayer insulating layer; and
a second bonding layer disposed between the first bonding layer and the second interlayer insulating layer and connected to the first bonding layer.

4. The semiconductor device of claim 2, wherein the first interlayer insulating layer and the second interlayer insulating layer each have first stress, and the first bonding layer and the second bonding layer each have second stress of a different type from the first stress.

5. The semiconductor device of claim 2, wherein the first bonding layer has a smaller thickness than the first interlayer insulating layer, and the second bonding layer has a smaller thickness than the second interlayer insulating layer.

6. The semiconductor device of claim 2, wherein the first bonding pad, the first bonding via, and the first dummy insulating pillar penetrate through the first bonding layer, and
the second bonding pad, the second bonding via, and the second dummy insulating pillar penetrate through the second bonding layer.

7. The semiconductor device of claim 1, wherein the first dummy insulating pillar is disposed at a level corresponding to the first bonding via, and
the second dummy insulating pillar is disposed at a level corresponding to the second bonding via.

8. The semiconductor device of claim 1, wherein the first dummy insulating pillar and the second dummy insulating pillar each include an insulating material, and
the first bonding via and the second bonding via each include a conductive material.

9. The semiconductor device of claim 7, wherein the first dummy insulating pillar and the second dummy insulating pillar each include oxide or nitride, and
the first bonding via and the second bonding via each include tungsten.

10. The semiconductor device of claim 1, wherein the first bonding pad and the second bonding pad each include copper.

11. The semiconductor device of claim 1, further comprising:
a gate structure disposed on the second bonding via;
channel structures extending through the gate structure; and
a source structure disposed on the gate structure and connected to the channel structures.

12. The semiconductor device of claim 1, further comprising:
a gate structure disposed over the second bonding via;
channel structures extending through the gate structure; and
a source structure disposed over the gate structure and connected to the channel structures.

13. A semiconductor device comprising:
a substrate including chip regions and a scribe lane region disposed between the chip regions;
a first interlayer insulating layer disposed in the chip regions and the scribe lane region;
a second interlayer insulating layer disposed on the first interlayer insulating layer;
a first bonding pad disposed in the first interlayer insulating layer, in the chip regions;
a second bonding pad disposed in the second interlayer insulating layer and connected to the first bonding pad;
a first bonding via penetrating through the first bonding pad;
a second bonding via penetrating through the second bonding pad and connected to the first bonding via;
a first dummy insulating pillar extending through the first interlayer insulating layer, in the scribe lane region; and
a second dummy insulating pillar extending through the second interlayer insulating layer and connected to the first dummy insulating pillar.

14. The semiconductor device of claim 13, wherein each of the chip regions includes cell regions and a peripheral circuit region surrounding the cell regions.

15. The semiconductor device of claim 14, wherein the first bonding pad, the second bonding pad, the first bonding via, and the second bonding via are disposed in the cell regions.

16. The semiconductor device of claim 14, further comprising:
a third dummy insulating pillar disposed at a level corresponding to the first dummy insulating pillar, in the peripheral circuit region; and
a fourth dummy insulating pillar disposed at a level corresponding to the second dummy insulating pillar and connected to the third dummy insulating pillar.

17. The semiconductor device of claim 13, further comprising:
a first bonding layer disposed on the first interlayer insulating layer; and
a second bonding layer disposed between the first bonding layer and the second interlayer insulating layer and connected to the first bonding layer.

18. The semiconductor device of claim 13, further comprising:
a first bonding layer disposed over the first interlayer insulating layer; and
a second bonding layer disposed between the first bonding layer and the second interlayer insulating layer and connected to the first bonding layer.

19. The semiconductor device of claim 17, wherein the first interlayer insulating layer and the second interlayer insulating layer each have first stress, and the first bonding layer and the second bonding layer each have second stress of a different type from the first stress.

20. The semiconductor device of claim 17, wherein the first bonding layer has a smaller thickness than the first interlayer insulating layer, and the second bonding layer has a smaller thickness than the second interlayer insulating layer.

21. The semiconductor device of claim 17, wherein the first bonding pad, the first bonding via, and the first dummy insulating pillar penetrate through the first bonding layer, and
the second bonding pad, the second bonding via, and the second dummy insulating pillar penetrate through the second bonding layer.

22. The semiconductor device of claim 13, wherein the first dummy insulating pillar is disposed at a level corresponding to the first bonding via, and
the second dummy insulating pillar is disposed at a level corresponding to the second bonding via.

23. The semiconductor device of claim 13, wherein the first dummy insulating pillar and the second dummy insulating pillar each include an insulating material, and
the first bonding via and the second bonding via each include a conductive material.

24. The semiconductor device of claim 23, wherein the first dummy insulating pillar and the second dummy insulating pillar each include oxide or nitride, and
the first bonding via and the second bonding via each include tungsten.

25. The semiconductor device of claim 13, wherein the first bonding pad and the second bonding pad each include copper.

26. The semiconductor device of claim 13, further comprising:
a gate structure disposed on the second bonding via, in the chip regions;
channel structures extending through the gate structure; and
a source structure disposed on the gate structure and connected to the channel structures.

27. The semiconductor device of claim 13, further comprising:
a gate structure disposed over the second bonding via, in the chip regions;
channel structures extending through the gate structure; and
a source structure disposed over the gate structure and connected to the channel structures.

28. A manufacturing method of a semiconductor device, the manufacturing method comprising:
forming an interlayer insulating layer on a substrate;
forming a bonding via and a first dummy bonding via extending through the interlayer insulating layer;
forming a trench exposing a portion of a sidewall of the bonding via;
forming a bonding pad in the trench using the bonding via and the first dummy bonding via as a planarization barrier;
forming a first dummy hole by removing the first dummy bonding via; and
forming a first dummy insulating pillar in the first dummy hole.

29. The manufacturing method of claim 28, further comprising forming a bonding layer on the interlayer insulating layer.

30. The manufacturing method of claim 28, further comprising forming a bonding layer over the interlayer insulating layer.

31. The manufacturing method of claim 29, wherein the interlayer insulating layer has first stress, and the bonding layer has second stress of a different type from the first stress.

32. The manufacturing method of claim 29, wherein the bonding layer is formed to have a smaller thickness than the interlayer insulating layer.

33. The manufacturing method of claim 29, wherein the bonding via and the first dummy bonding via extend through the bonding layer and the interlayer insulating layer.

34. The manufacturing method of claim 28, wherein the substrate includes chip regions and a scribe lane region disposed between the chip regions, and
the bonding via is formed in the chip regions, and the first dummy bonding via is formed in the scribe lane region.

35. The manufacturing method of claim 34, wherein each of the chip regions includes cell regions and a peripheral circuit region surrounding the cell regions.

36. The manufacturing method of claim 35, wherein a second dummy bonding via is formed in the peripheral circuit region when the bonding via and the first dummy bonding via are formed.

37. The manufacturing method of claim 36, further comprising:
forming a second dummy hole by removing the second dummy bonding via; and
forming a second dummy insulating pillar in the second dummy hole.

38. The manufacturing method of claim 37, wherein the second dummy hole is formed simultaneously when the first dummy hole is formed.

39. The manufacturing method of claim 37, wherein the second dummy insulating pillar is formed simultaneously when the first dummy insulating pillar is formed.

40. A manufacturing method of a semiconductor device, the manufacturing method comprising:
forming a first interlayer insulating layer on a first substrate including first chip regions and a first scribe lane region disposed between the first chip regions;
forming a first bonding via and a first dummy bonding via in the first interlayer insulating layer, the first bonding via being disposed in the first chip regions, and the first dummy bonding via being disposed in the first scribe lane region;
forming a first bonding pad surrounding a portion of a sidewall of the first bonding via;
forming a first dummy hole by removing the first dummy bonding via; and
forming a first dummy insulating pillar in the first dummy hole.

41. The manufacturing method of claim 40, wherein the forming of the first bonding pad comprises:
forming a trench exposing the portion of the sidewall of the first bonding via;
forming the first bonding pad in the trench using the first bonding via and the first dummy bonding via as a planarization barrier.

42. The manufacturing method of claim 40, further comprising forming a bonding layer on the first interlayer insulating layer.

43. The manufacturing method of claim 40, further comprising forming a bonding layer over the first interlayer insulating layer.

44. The manufacturing method of claim 42, wherein the first interlayer insulating layer has first stress, and the bonding layer has second stress of a different type from the first stress.

45. The manufacturing method of claim 42, wherein the bonding layer is formed to have a smaller thickness than the first interlayer insulating layer.

46. The manufacturing method of claim 42, wherein the first bonding via and the first dummy bonding via extend through the bonding layer and the first interlayer insulating layer.

47. The manufacturing method of claim 40, further comprising:
forming a first wafer including the first substrate, the first interlayer insulating layer, the first bonding via, the first bonding pad, and the first dummy insulating pillar;
forming a second wafer including a second substrate including second chip regions and a second scribe lane region disposed between the second chip regions, a second interlayer insulating layer formed on the second substrate, a gate structure formed in the second chip regions, channel structures extending through the gate structure, a second bonding via disposed on the gate structure, a second bonding pad surrounding a portion of a sidewall of the second bonding via, and a second dummy insulating pillar formed in the second scribe lane region; and
bonding the first wafer and the second wafer to each other so that the first bonding pad and the second bonding pad are connected to each other, the first bonding via and the second bonding via are connected to each other, and the first dummy insulating pillar and the second dummy insulating pillar are connected to each other.

48. The manufacturing method of claim 40, further comprising:
forming a first wafer including the first substrate, the first interlayer insulating layer, the first bonding via, the first bonding pad, and the first dummy insulating pillar;
forming a second wafer including a second substrate including second chip regions and a second scribe lane region disposed between the second chip regions, a second interlayer insulating layer formed over the second substrate, a gate structure formed in the second chip regions, channel structures extending through the gate structure, a second bonding via disposed over the gate structure, a second bonding pad surrounding a portion of a sidewall of the second bonding via, and a second dummy insulating pillar formed in the second scribe lane region; and
bonding the first wafer and the second wafer to each other so that the first bonding pad and the second bonding pad are connected to each other, the first bonding via and the second bonding via are connected to each other, and the first dummy insulating pillar and the second dummy insulating pillar are connected to each other.

49. The manufacturing method of claim 47, further comprising:
exposing the channel structures by removing the second substrate; and
forming a source structure connected to the channel structures.

50. The manufacturing method of claim 47, wherein each of the first chip regions includes first cell regions and a first peripheral circuit region surrounding the first cell regions, and
each of the second chip regions includes second cell regions and a second peripheral circuit region surrounding the second cell regions.

51. The manufacturing method of claim 50, wherein the second dummy insulating pillar is formed in a second dummy hole formed by removing a second dummy bonding via after forming the second dummy bonding via when forming the second bonding via.

52. The manufacturing method of claim 51, wherein in the first wafer, a third dummy bonding via is formed in the first peripheral circuit region when the first dummy bonding via is formed, and
in the second wafer, a fourth dummy bonding via is formed in the second peripheral circuit region when the second dummy bonding via is formed.

53. The manufacturing method of claim 52, further comprising:
forming a third dummy hole by removing the third dummy bonding via;
forming a third dummy insulating pillar in the third dummy hole;
forming a fourth dummy hole by removing the fourth dummy bonding via; and
forming a fourth dummy insulating pillar in the fourth dummy hole.

54. The manufacturing method of claim 53, wherein the third dummy hole is formed simultaneously when the first dummy hole is formed, and
the fourth dummy hole is formed simultaneously when the second dummy hole is formed.

55. The manufacturing method of claim 53, wherein the third dummy insulating pillar is formed simultaneously when the first dummy insulating pillar is formed, and
the fourth dummy insulating pillar is formed simultaneously when the second dummy insulating pillar is formed.
